(19) United States
(12) Patent Application Publication
(10) Pub. No.: US 2011/0297920 A1
(43) Pub. Date: Dec. 8, 2011

(54) THIN FILM TRANSISTOR,METHOD OF MANUFACTURING THE SAME, AND ELECTRONIC DEVICE

(75) Inventor: Toshio Fukuda, Kanagawa (JP)

(73) Assignee: Sony Corporation, Tokyo (JP)

(21) Appl. No.: 13/108,428

(22) Filed: May 16, 2011

(30) Foreign Application Priority Data
Jun. 3, 2010 (JP) 2010-127896

(51) Int. Cl. H01L 51/10; H01L 51/40

(52) U.S. Cl. 257/40; 438/99; 257/E51.005; 257/E51.024

(57) ABSTRACT

A thin film transistor with improved performance is provided. The thin film transistor includes a gate electrode, an organic semiconductor layer, and a gate insulating layer which is positioned between the gate electrode and the organic semiconductor layer and is adjacent to the organic semiconductor layer. The gate insulating layer contains a material in which a first monomer as at least one of styrene and a derivative of styrene, and a second monomer having carbon-carbon double bond and a cross-linking reaction group are copolymerized and cross-linked.

### BACKGROUND

The present disclosure relates to a thin film transistor having an organic semiconductor layer as a channel layer, a method of manufacturing the same, and an electronic device having the thin film transistor.

In recent years, attention is paid to a thin film transistor (TFT) using an organic semiconductor layer as a channel layer, which is called an organic TFT. In an organic TFT, an organic semiconductor layer is disposed so as to be opposed to a gate electrode with a gate insulating layer in between.

An organic TFT is regarded as a promising device replacing an existing inorganic TFT using an inorganic semiconductor layer as a channel layer and is applied to various electronic devices including a display device. In comparison to an inorganic TFT, an organic TFT has some advantages. First, since an organic semiconductor layer is formed by coating, lower cost is realized. Second, since an organic semiconductor layer is formed at temperature lower than that in vapor deposition, the organic TFT is mountable on a substrate such as low-heat-resistance plastic film or the like. Third, by chemically modifying an organic semiconductor material (by introducing a desired functional group or the like), the physical property of the organic semiconductor layer is controlled.

In particular, by mounting an organic TFT on a flexible substrate such as a plastic film, a foldable electronic device is realized by utilizing the flexibility. In this case, an organic semiconductor layer is formed at temperature lower than that in the vapor deposition method, so that the substrate is prevented from being thermally damaged. Therefore, a method of forming an organic semiconductor layer by using the printing method or the like is proposed (see, for example, WO 2003/016599).

### SUMMARY

To improve the performance of an organic TFT, the characteristics of a gate insulating layer which insulates an organic semiconductor layer from a gate electrode are significant. As the characteristics of the gate insulating layers, solvent resistance, thermal stability, denseness, and the like are necessary.

However, the characteristics of the gate insulating layer in an organic TFT of related art are not sufficient yet. In particular, when an organic semiconductor material having low solvent resistance is used, the gate insulating layer is easily dissolved by an organic solvent in a photolithography process or the like.

It is therefore desirable to provide a thin film transistor with improved performance, a method of manufacturing the same, and an electronic device.

A thin film transistor according to an embodiment of the present disclosure has a gate electrode, an organic semiconductor layer, and a gate insulating layer which is positioned between the gate electrode and the organic semiconductor layer and is adjacent to the organic semiconductor layer. The gate insulating layer contains a material in which a first monomer as at least one of styrene and a derivative of styrene, and a second monomer having carbon-carbon double bond and a cross-linking reaction group are copolymerized and cross-linked. An electronic device of an embodiment of the present disclosure has the above-mentioned thin film transistor.

A method of manufacturing a thin film transistor of an embodiment of the present disclosure includes: forming a gate electrode; forming an organic semiconductor layer; and forming a gate insulating layer between the gate electrode and the organic semiconductor layer so as to be adjacent to the organic semiconductor layer, the gate insulating layer containing a material in which a first monomer as at least one of styrene and a derivative of styrene, and a second monomer having carbon-carbon double bond and a cross-linking reaction group are copolymerized and cross-linked.

In the thin film transistor, the method of manufacturing the same, and the electronic device of the embodiment of the present disclosure, the gate insulating layer which is adjacent to the organic semiconductor layer contains the above-described material (cross-linked copolymer material). Therefore, the solvent resistance, thermal stability, and denseness of the gate insulating layer are improved, so that the performances are improved.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a cross section illustrating the configuration of a thin film transistor of an embodiment of the present disclosure.

FIG. 2 is a cross section for explaining a method of manufacturing the thin film transistor.

FIG. 3 is a cross section for explaining a process subsequent to FIG. 2.

FIG. 4 is a cross section for explaining a process subsequent to FIG. 3.

FIG. 5 is a cross section for explaining a process subsequent to FIG. 4.

FIG. 6 is a cross section for explaining a process subsequent to FIG. 5.

FIG. 7 is a cross section for explaining a process subsequent to FIG. 6.

FIG. 8 is a cross section for explaining a first modification on the configuration of the thin film transistor.

FIG. 9 is a cross section for explaining a second modification on the configuration of the thin film transistor.

FIG. 10 is a cross section for explaining a third modification on the configuration of the thin film transistor.

FIG. 11 is a cross section illustrating the configuration of a liquid crystal display of an example of application of the thin film transistor.

FIG. 12 is a diagram illustrating the circuit configuration of the liquid crystal display shown in FIG. 11.

### DETAILED DESCRIPTION OF THE PREFERRED EMBODIMENTS

In the following, an embodiment of the present disclosure will be described in detail with reference to the drawings. The description will be given in the following order.

1. Thin film transistor

1-1. The configuration of thin film transistor

1-2. Method of manufacturing thin film transistor

2. Application example of thin film transistor (electronic device)

### 1. Thin Film Transistor

### 1-1. The Configuration of Thin Film Transistor

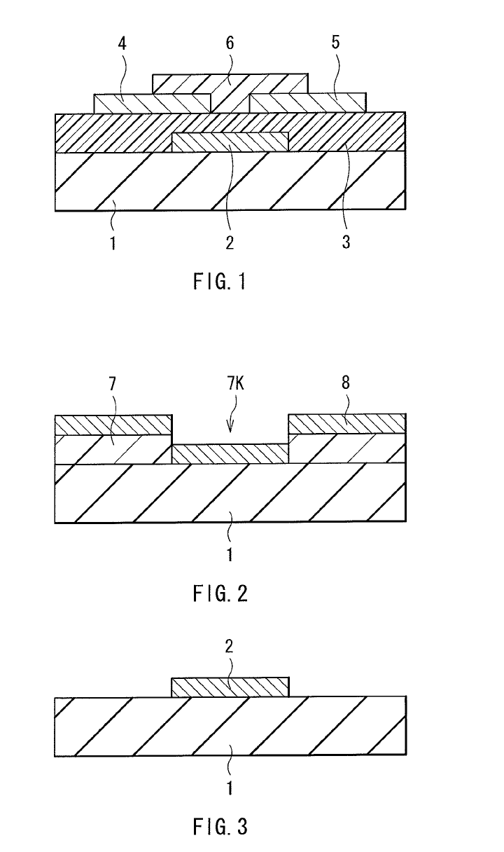

FIG. 1 illustrates a sectional configuration of an organic TFT as a thin film transistor of an embodiment of the present disclosure.

In the organic TFT, an organic semiconductor layer 6 as a channel layer is disposed so as to be opposed to a gate electrode 2 with a gate insulating layer 3 therebetween, and a source electrode 4 and a drain electrode 5 are connected to the organic semiconductor layer 6.

For example, on a substrate 1, the gate electrode 2, the gate insulating layer 3, the source electrode 4 and the drain electrode 5, and the organic semiconductor layer 6 are stacked in this order. This organic TFT is of a bottom-gate bottom-contact type in which the gate electrode 2 is positioned on the lower side (the side closer to the substrate 1) of the organic semiconductor layer 6, and the organic semiconductor layer 6 is provided on the source electrode 4 and the drain electrode 5.

The substrate 1 is made of one or more of a plastic material, a metal material, and an inorganic material.

Examples of the plastic material include polymethylmethacrylate (PMMA), polyvinyl alcohol (PVA), polyvinyl phenol (PVP), polyether sulfone (PES), polycarbonate (PC), polyimide (PI), polyethylene terephthalate (PET), polyethylene naphthalate (PEN), and polyetheretherketone (PEEK). Examples of the metal material include aluminum, nickel, and stainless steel. Examples of the inorganic materials include silicon (Si), silicon oxide (SiOx), silicon nitride (SiNx), aluminum oxide (AlOₓ), and other metal oxides. The silicon oxide includes silicon oxide materials such as glass, quartz, and spin-on-glass (SOG).

The substrate 1 may be a substrate having rigidity such as a wafer or a film having flexibility. The surface of the substrate 1 may be provided with any of various coating layers having predetermined functions such as a buffer layer for assuring adhesion and a gas barrier layer for preventing gas release.

The substrate 1 may be made of a single layer or multiple layers. In the case of multiple layers, two or more layers of the above-described various materials may be stacked. Similarly, each of the gate electrode 2, the gate insulating layer 3, the source electrode 4, the drain electrode 5, and the organic semiconductor layer 6 may be made of a single layer or multiple layers.

The gate electrode 2 is made of, for example, one or more of a metal material, an inorganic conductive material, an organic conductive material, and a carbon material.

Examples of the metal material include aluminum (Al), copper (Cu), molybdenum (Mo), titanium (Ti), chromium (Cr), nickel (Ni), palladium (Pd), gold (Au), silver (Ag), platinum (Pt), tantalum (Ta), tungsten (W), indium (In), tin (Sn), iron (Fe), cobalt (Co), zinc (Zn), and magnesium (Mg) and alloys containing the metal materials. Examples of the inorganic conductive material include polysilicon, indium oxide (In₂O₃), indium tin oxide (ITO), indium zinc oxide (IZO), and zinc oxide (ZnO). Examples of the organic conductive material include polyethylenedioxythiophene (PEDOT), polystyrene sulfonate (PSS), and polyaniline. The carbon material is, for example, graphite.

The gate insulating layer 3 is positioned between the gate electrode 2 and the organic semiconductor layer 6 and is adjacent to the organic semiconductor layer 6. The gate insulating layer 3 contains an insulating material (cross-linked copolymer material) in which specific two kinds of monomers (first and second monomers) are copolymerized and cross-linked.

The gate insulating layer 3 is adjacent to the organic semiconductor layer 6 for a reason that, since the gate insulating layer 3 is a layer adjacent to the passage (the organic semiconductor layer 6) of electrons when the organic TFT operates, the gate insulating layer 3 has to contain a cross-linked copolymer material for alignment control which will be described below.

The gate insulating layer 3 contains a cross-linked copolymer material for the following reasons. First, excellent insulating property is obtained. Second, the solvent resistance and thermal stability of the gate insulating layer 3 improve. Consequently, the gate insulating layer 3 is not easily dissolved by an organic solvent and becomes insusceptible to thermal damage in a process of manufacturing an organic TFT. Third, the denseness of the gate insulating layer 3 improves, so that dielectric strength voltage between the gate electrode 2 and the organic semiconductor layer 6 becomes higher. Fourth, the orientation of the organic semiconductor layer is excellently controlled at the time of forming the organic semiconductor layer 6, and the adverse influence of the gate insulating layer 3 on the orientation of the organic semiconductor material is suppressed.

The first monomer is at least one of styrene and any of derivatives of styrene. That is, the first monomer may be styrene, one or more of derivatives of styrene, or a mixture of styrene and one or more of derivatives of styrene. The first monomer has a styrene skeleton (benzene ring and carbon-carbon double bond which is bonded to the benzene ring) mainly for reasons that excellent insulating property is easily obtained by the benzene ring and the first monomer is stably and easily copolymerized with the second monomer by the carbon-carbon double bond.

A derivative of styrene is obtained by introducing one or more substituents in styrene. Although the kind of the substituent is not limited, hydrocarbon group is preferable among substituents for a reason that the substituent does not easily exert influence on the chemical property of a derivative. The hydrocarbon group is, for example, at least one of alkyl group, alkenyl group, alkynyl group, aryl group, and cycloalkyl group. In the case where the substituent is in a chain shape (alkyl group, alkenyl group, or alkynyl group), although not limited, the smaller the carbon number is, the more preferable. The carbon number is, preferably, 3 or less and, more preferably, 2 or less. The reason is that, since steric hindrance hardly occurs, the first monomer is stably and easily copolymerized with the second monomer.

As the substituent, the alkyl group is preferable for reasons such that the substituent does not easily exert influence on the chemical property of a derivative and the first monomer is stably and easily copolymerized with the second monomer. Consequently, as a derivative of styrene, alkyl styrene having one or more alkyl groups is preferable. Examples of alkyl styrene include α-methylstyrene, α-ethylstyrene, α-butylstyrene, and 4-methylstyrene, and particularly, α-methylstyrene, α-ethylstyrene, and 4-methylstyrene whose carbon number is 2 or less are more preferable.

The second monomer is a material having carbon-carbon double bond and cross-linking reaction group. When the second monomer has a cross-linking reaction group, a copolymer material (a material obtained by copolymerizing the first and second monomers) is cross-linked, the solvent resistance, thermal stability, and denseness of the gate insulating layer 3 are improved, and the orientation of the organic semiconductor material is excellently controlled at the time of forming the organic semiconductor layer 6. The carbon-carbon double bond is used for the second monomer to be copolymerized with the first monomer.

The cross-linking reaction group is a group of cross-linking a copolymer material by forming a cross-linking network. Since a copolymer is cross-linked (cured) by the cross-linking reaction group, the solvent resistance and the like of the gate insulating layer 3 are improved and the orientation of the organic semiconductor material is excellently controlled. The curing type of the cross-linking reaction group may be thermal curing, energy line curing, or the like. Obviously, the second monomer may have two or more kinds of cross-linking reaction groups of different curing types.

Although the kind of the cross-linking reaction group is not limited, at least one of an epoxy group (—C₂H₃O), a glycidyl group (—CH₂—C₂H₃O), a hydroxyl group (—OH), an acryloyl group (—CO—CH═CH₂), a methacryloyl group (—CO—C(CH₃)═CH₂), and an alyl group (—CH₂—CH═CH₂) is preferable for a reason that a cross-linking network is stably and easily formed.

In the case where the second monomer has the epoxy group or glycidyl group, a cross-linking reaction occurs by, for example, heating. In the case where the second monomer has the hydroxyl group, a cross-linking reaction occurs by, for example, heating (a reaction with isocyanate, melamine, or the like). In the case where the second monomer has the acryloyl group, the methacryloyl group, or the allyl group, a cross-linking reaction occurs by, for example, heating using peroxide or the like or irradiation of ultraviolet light using an initiator of radical polymerization or the like.

The kind of a part other than the cross-linking reaction group (a linking group which is linked to the cross-linking reaction group) is not limited as long as it has the carbon-carbon double bond. Examples of the linking group include methacryloyl group, acryloyl group, allyl group, and a group obtained by linking another group (spacer) to those groups. The spacer is, for example, alkylene group, polyoxyalkylene group, or the like. Although the carbon number of the alkylene group is not limited, it is preferably 1 to 30 both inclusive. The polyoxyalkylene group is, for example, polyoxyethylene group ([—CH₂CH₂O—]ₙ: n is an integer of 1 or larger) or polyoxypropylene group ([—CH₂CH₂CH₂O—]ₙ).

The kind of the second monomer is not limited as long as it has, as described above, the carbon-carbon double bond and the cross-linking reaction group. For example, the second monomer having the glycidyl group as the cross-linking reaction group is glycidyl methacrylate, glycidyl acrylate, or allylglycidylether.

Although the molecular weight (weight-average molecular weight Mw) of the cross-linking copolymer material is not limited, it is preferably 5,000 to 1,000,000 both inclusive. The excellent characteristics are obtained and the material is stably easily dissolved in many organic solvents. The solubility is an advantageous when the gate insulating layer 3 is formed by using a solution technique such as coating or printing.

The gate insulating layer 3 may contain another insulating material together with the cross-linking copolymer material. The other insulating material is, for example, one or more kinds of either an inorganic insulating material or an organic insulating material. Examples of the inorganic insulating material include silicon oxide, silicon nitride, aluminum oxide, titanium oxide (TiO₂), hafnium oxide (HfOₓ), and barium titanate (BaTiO₃). Examples of the organic insulating material include polyvinylphenol (PVP), polyimide, polymethacrylate acrylate, photosensitive polyimide, photosensitive novolac resin, and polyparaxylylene.

The gate insulating layer 3 may not be adjacent to the gate electrode 2. In the case where the gate insulating layer 3 is not adjacent to the gate electrode 2, for example, one or more other gate insulating layers are inserted between the gate electrode 2 and the gate insulating layer 3. The material of the gate insulating layer is, for example, similar to another insulating material contained together with the cross-linking copolymer material in the gate insulating layer 3.

The source electrode 4 and the drain electrode 5 are formed by, for example, a material similar to that of the gate electrode 2 and are preferably in ohmic-contact with the organic semiconductor layer 6. The material of the source electrode 4 and the drain electrode 5 may be the same as that of the gate electrode 2 or different from that of the gate electrode 2.

The organic semiconductor layer 6 is formed by, for example, any one or more of the following organic semiconductor materials: (1) polypyrrole; (2) polythiophene; (3) isothianaphthene such as polyisothianaphthene; (4) thenylenevinylene such as polythenylenevinylene, (5) p-phenylenevinylene such as poly(p-phenylenevinylene); (6) polyaniline; (7) polyacetylene; (8) polydiacetylene; (9) polyazulene; (10) polypyrene; (11) polycarbazole; (12) polyselenophene; (13) polyfuran; (14) poly(p-phenylene); (15) polyindole; (16) polypridazine; (17) acene such as naphthacene, pentacene, hexacene, heptacene, dibenzopentacene, tetrabenzopentacene, pyrene, dibenzopyrene, chrysene, perylene, coronene, Terrylene, ovalene, quaterrylene, or circumanthracene; (18) a derivative obtained by substituting a part of carbon in acenes with an atom of nitrogen (N), sulfur (S), oxygen (O), or the like or a functional group such as carbonyl group, for example, triphenodioxazine, triphenodithiazine, Hexacene-6,15-quinone, or the like; (19) a high polymer material and polycyclic condensation product such as polyvinylcarbazole, polyphenylene sulfide, or polyvinylene sulfide; (20) an olygomer having the same repeating unit as that of the above-described high polymer material; (21) metal phthalocyanine such as copper phthalocyanine; (22) tetrathiafulvalene; (23) tetrathiapenthalene; (24) N,N′-bis(1H,1H-perfluorooctyl), N,N′-bis(1H,1H-perfluorobutyl), or N,N′-dioctylnaphthalene 1,4,5,8-tetracarboxylic diimide derivative with naphthalene-1,4,5,8-tetracarboxylic diimide or N,N′-bis(4-trifluoromethylbenzyl) naphthalene 1,4,5,8-tetracarboxylic diimide; (25) naphthalene tetracarboxyric diimide such as naphthalene 2,3,6,7 tetracarboxyric diimide; (26) condensed-ring tetracarboxyric diimide typified by anthracene tetracarboxyric diimide such as anthracene 2,3,6,7-tetracarboxyric diimide; (27) fullerene such as C₆₀/C₇₀, C₇₆, C₇₈, or C₈₄; (28) carbon nanotube such as single-wall nanotube (SWNT); (29) dye such as merocyanine dye or hemicyanine dye; and (30) peri-Xanthenoxanthene compound such as 2,9-dinaphthyl-peri-Xanthenoxanthene. The organic semiconductor material may be derivatives of the above-described series of materials.

### 1-2. Method of Manufacturing Thin Film Transistor

FIGS. 2 to 7 are diagrams for explaining a method of manufacturing the organic TFT and illustrate sectional configurations corresponding to FIG. 1. Since the formation materials of the series of components have been described already, the description will not be repeated below.

First, as shown in FIG. 2, a photoresist pattern 7 having an opening 7K is formed on the substrate 1. The opening 7K is a space for forming the gate electrode 2 in a post-process. In the case of forming the photoresist pattern 7, for example, a photoresist film (not shown) is formed by applying photoresist on the surface of the substrate 1 and is patterned. A method of patterning the photoresist film is, for example, photolithography, laser lithography, electron-beam lithography, X-ray lithography, or the like. The photoresist pattern 7 may be formed by using a resist transfer method or the like.

Subsequently, an electrode layer 8 is formed so as to cover the photoresist pattern 7 and the opening 7K (the exposed face of the substrate 1). The method of forming the electrode layer 8 is, for example, physical vapor deposition (PVD), chemical vapor deposition (CVD), the lift-off method, the shadow mask method, the plating method, or the like. Examples of the PVD include (1) vacuum evaporation such as electron-beam evaporation, resistive heating, flash evaporation, or crucible heating, (2) plasma deposition, (3) sputtering such as double-pole sputtering, DC sputtering, DC magnetron sputtering, RF sputtering, magnetron sputtering, ion beam sputtering, or bias sputtering, and (4) ion plating such as DC ion plating, RF ion plating, multi-cathode ion plating, activation reaction ion plating, electric field evaporation ion plating, RF ion plating, or reactive ion plating. The CVD is, for example, metal organic CVD (MOCVD). The plating method is, for example, electrolytic plating or electroless plating.

In the case of using vacuum evaporation or the like in which formation temperature tends to be high as the method of forming the electrode layer 8, it is preferable to use a support holder (not illustrated) as a supporting member of the substrate 1 to suppress thermal deformation or the like of the substrate 1.

An adhesion layer (not illustrated) for enhancing adhesion of the electrode layer 8 to the substrate 1 may be formed before the electrode layer 8 is formed. The material of the adhesion layer is, for example, a metal material such as tantalum and a method of forming the adhesion layer is, for example, the same as the method of forming the electrode layer 8.

Subsequently, the photoresist pattern 7 is removed together with a part of the electrode layer 8 by using the lift-off method. A method of removing the photoresist pattern 7 is ashing or the like. As a result, as illustrated in FIG. 3, the gate electrode 2 is pattern-formed on the substrate 1.

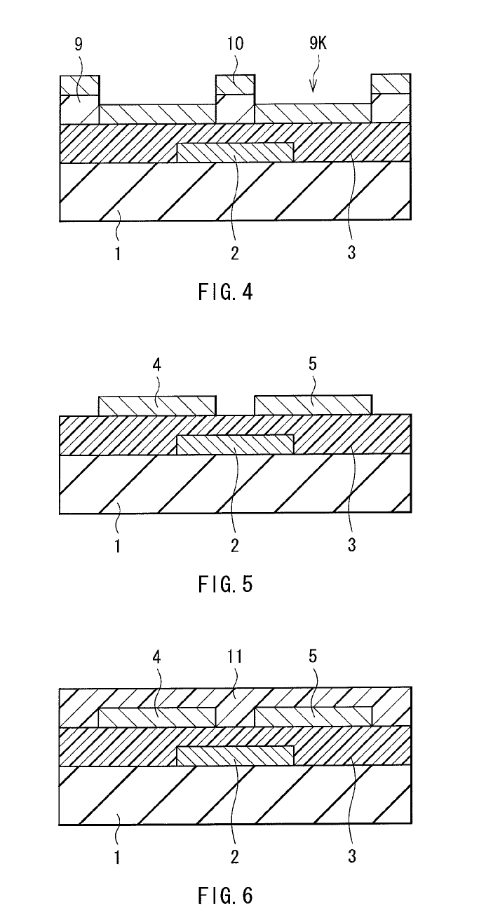

After that, as illustrated in FIG. 4, the gate insulating layer 3 is formed so as to cover the gate electrode 2 and the substrate 1 in the periphery of the gate electrode 2.

In this case, first, a copolymer material is obtained by mixing first and second monomers, dissolving the resultant into an organic solvent or the like, and copolymerizing the first and second monomers. In the case of mixing the first and second monomers, it is preferable to set the proportion (weight) of the first monomer to be larger than that of the second monomer for a reason that the insulation property as a main function of the gate insulating layer 3 is obtained mainly from the first monomer. In the case of copolymerizing the first and second monomers, another material such as a polymerization initiator or molecular weight modifier may be also mixed as necessary.

Examples of the mixing ratio of the first and second monomers are as follows. The proportion of the first monomer is, preferably, 50 weight % to 99 weight % both inclusive and, more preferably, 70 weight % to 97 weight % both inclusive. When the proportion is less than 50 weight %, the insulating property is low and there is the possibility that the orientation of the organic semiconductor layer 6 (organic semiconductor material) is not sufficiently controlled. The proportion of the second monomer is, preferably, 1 weight % to 50 weight % both inclusive and, more preferably, 3 weight % to 30 weight % both inclusive. When the proportion is less than 1 weight %, there is the possibility that sealing performance, heat resistance, and cross-linking performance are low. When the proportion is higher than weight %, there is the possibility that machining performance deteriorates due to strong thermal contraction at the time of cross linking, and water absorbability and electric permittivity becomes high due to increase in the polar component. A concrete mixing ratio (weight ratio) between the first and second monomers is, preferably, 1:1 to 50:1 both inclusive, more preferably, 10:1 to 50:1 both inclusive and, furthermore preferably, 20:1 to 50:1 both inclusive.

Subsequently, a cross-linked copolymer material is obtained by mixing the copolymer material with another material such as a curing agent or catalyst as necessary, dissolving the resultant into an organic solvent or the like, and cross-linking the copolymer material. To cross-link the copolymer material, for example, the material is heated or irradiated with an energy beam in accordance with the kind of a cross-linking reaction group of the second monomer. It is sufficient that the addition amount of the curing agent and the catalyst be equivalent to that of the cross-linking reaction group. Concretely, for example, in the case where the cross-linking reaction group is an epoxy group, the addition amount of the curing agent and catalyst is, preferably, 0.01 parts by weight to 50 parts by weight both inclusive for 100 parts by weight of the copolymer material and, more preferably, 0.1 parts by weight to 20 parts by weight both inclusive. In particular, the addition amount of an epoxy group of a thermal curing type is, preferably, 0.01 parts by weight to 5 parts by weight both inclusive for 100 parts by weight of the copolymer material. The addition amount of an epoxy group of an energy beam curing type, preferably, 1 parts by weight to 50 parts by weight both inclusive for 100 parts by weight of the copolymer material. The copolymer reaction and the cross-linking reaction may be performed simultaneously, not separately.

Examples of the curing agent include 3-methyl-1,2,3,6-tetrahydrophthalic acid anhydride or 4-methyl-1,2,3,6-tetrahydrophthalic acid anhydride.

Examples of the material of the catalyst for thermal curing include: (1) chain aliphatic primary diamine such as polymethylene diamine, dipropylene diamine, or trimethyl hexamethylene diamine; (2) chain aliphatic primary polyamine such as iminobispropylamine, 1,3,6-triaminomethylhexane, or tetraethylenepentamine; (3) alicyclic polyamine such as N-aminoethyl piperazine or bis(4-amino-3-methylcyclohexyl)methane; (4) aromatic-containing aliphatic primary amine such as meta xylylene diamine; (5) aromatic primary amine such as meta phenylene diamine, 2,4-diaminodiphenylamine, or diaminodiphenyl sulfone; (6) secondary amine such as dimethylamine or diethylamine; (7) tertiary amine such as dimethylcyclohexylamine, pyridine, or α-picoline; (8) aromatic acid anhydride such as phthalic anhydride, pyromellitic anhydride, or glylerol tris(anhydro trimellitate); (9) cyclic aliphatic anhydride such as maleic anhydride, methyltetrahydrophthalic anhydride, or methylcyclohexene tetracarboxylic anhydride; (10) aliphatic acid anhydride such as polyadipic anhydride, polyazelaic anhydride, or polysebacic anhydride; (11) polyamide resin obtained by condensation reaction of dimer acid and polyamine; (12) imidazoles such as 2-methylimidazole, 1-cyanoethyl-2-ethyl-4-methylimidazole, or 1-cyanoethyl-2-phenylimidazolinium trimellitate; (13) latent curing agent such as boron trifluoride-amine complex, organic acid hydrazide, or salt of polyamine; (14) polymercaptan such as liquid polymercaptan or polysulfide; and (15) a synthetic resin initial condensation product such as novolac-type phenolic resin or polyvinylphenol.

Examples of the material of the catalyst for curing energy beam include: (1) aryldiazonium salt such as phenyldiazonium tetrafluoroborate or 4-methoxyphenyldiazonium hexafluorophosphate; (2) diaryliodonium salt such as diphenyliodonium tetrafluoroborate or di(4-butylphenyl)iodonium hexafluorophosphate; (3) triarylsulfonium salt such as triphenylsulfonium hexafluorophosphate, triphenylsulfonium tetrafluoroborate, or tris(4-methoxyphenl)sulfonium hexafluorophosphate; (4) dialkyl phenacyl sulfonium salt such as dimethylphenacyl sulfonium hexafluorophosphate or phenacyl tetramethylene sulfonium tetrafluoroborate; (5) dialkyl-4-hydroxyphenyl sulfonium salt such as 3,5-dimethyl-4-hydroxyphenyl sulfonium tetrafluoroborate or 3,5-dibutyl-4-hydroxyphenyl sulfonium hexafluoroantimonate; (6) sulfonate ester such as α-hydroxymethyl benzoin sulfonate ester, N-hydroxyimidesulfonate, or α-sulfonyloxyketone; (7) triazine compound such as 2-(4-methoxyphenyl)-4,6-di(trichloromethyl)triazine; and (8) diazonaphthoquinone compound such as orthodiazonaphtoquinone-4-sulfonate ester or orthodiazonaphtoquione-5-sulfonate ester.

The another material to be mixed with the copolymer material may be a material other than the curing agent and the catalyst. Examples of the another material include a hardening accelerator, a mold release agent, a flexibilizer, a coupling agent, and a filler.

Finally, the cross-linked copolymer material is dissolved in an organic solvent or the like to prepare a solution, and the solution is applied and dried. The organic solvent used to prepare the solution is, for example, one or more kinds of aromatic hydrocarbon, ketone, non-aromatic hydrocarbon, and the like. Examples of the aromatic hydrocarbon include toluene, xylene, mesitylene, and tetralin. Ketone is, for example, cyclopentanone, cyclohexanone, or the like. The non-aromatic hydrocarbon is, for example, decalin. The organic solvent may be propylene glycol monomethyl ether acetate (PGMEA) or the like. Examples of the solution coating method include coating, printing, dipping, casting, and the sol-gel method. The coating method is, for example, spin coating, slit coating, bar coating, or spray coating. Examples of the printing method include ink jet printing, screen printing, gravure printing, and gravure offset printing. As a result, the gate insulating layer 3 is formed.

Subsequently, by a procedure similar to that in the case of forming the photoresist pattern 7 (FIG. 2), a photoresist pattern 9 having an opening 9K is formed on the gate insulating layer 3. The opening 9K is a space for forming the source electrode 4 and the drain electrode 5 in a post process.

After that, by a procedure similar to that in the case of forming the electrode layer 8, an electrode layer 10 is formed so as to cover the photoresist pattern 9 and the opening 9K (the exposed face of the gate insulating layer 3).

The photoresist pattern 9 is removed together with a part of the electrode layer 10 by using the lift-off method. The photoresist pattern 9 is removed by, for example, a method similar to that of removing the photoresist pattern 7. As a result, as illustrated in FIG. 5, the source electrode 4 and the drain electrode 5 are pattern-formed on the gate insulating layer 3.

Subsequently, as illustrated in FIG. 6, an organic semiconductor layer 11 is formed so as to cover the source electrode 4, the drain electrode 5, and the gate insulating layer 3 in the periphery of the electrodes. In the case of forming the organic semiconductor layer 11, for example, a solution is prepared by dissolving the organic semiconductor material in an organic solvent or the like. After that, the solution is applied to the source electrode 4, the drain electrode 5, and the gate insulating layer 3 in the periphery of the electrodes by the coating method or the like and dried. The organic solvent used for preparing the solution is similar to that used for forming the gate insulating layer 3 and, particularly, a high-boiling aromatic hydrocarbon (mesitylene, tetralin, decalin, or the like) is preferable. The material of the organic semiconductor layer 11 is similar to that of the organic semiconductor layer 6.

Finally, the organic semiconductor layer 11 is etched to pattern-form the organic semiconductor layer 6 as illustrated in FIG. 1. Although the method of etching the organic semiconductor layer 11 is not limited, a preferable etching method is wet etching which hardly exerts influence on the source electrode 4, the drain electrode 5, and the gate insulating layer 3 at the time of etching. As a result, an organic TFT is completed.

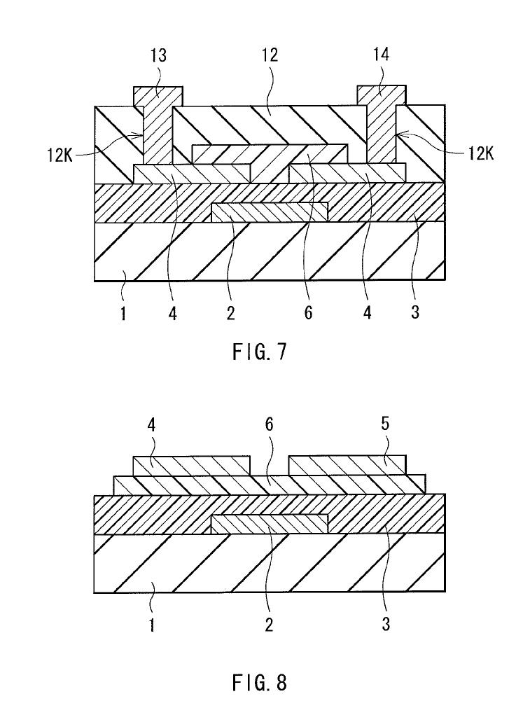

As illustrated in FIG. 7, as necessary, an insulating layer 12 may be formed so as to cover the gate insulating layer 3, the source electrode 4, the drain electrode 5, and the organic semiconductor layer 6. In this case, wirings 13 and 14 may be formed so as to be connected to the source electrode 4 and the drain electrode 5, respectively, in openings 12K provided in the insulating layer 12. For example, the material of the insulating layer 12 is silicon oxide and the method of forming the same is vacuum evaporation. For example, the material and the method of forming the wirings 13 and 14 are similar to those of the source electrode 4 and the drain electrode 5.

Operation and Effect on Thin Film Transistor and Method of Manufacturing the Same

In the organic TFT and the method of manufacturing the same, the gate insulating layer 3 adjacent to the organic semiconductor layer 6 contains the cross-linked copolymer material. Since the solvent resistance and the thermal stability of the gate insulating layer 3 improve, the gate insulating layer 3 is not easily dissolved by the organic solvent and becomes insusceptible to thermal damage in the organic TFT manufacturing process. In addition, the denseness of the gate insulating layer 3 improves, so that dielectric strength voltage becomes higher. Therefore, mobility, the on-off ratio, and the like improve, so that the performance is improved.

In particular, when the first monomer is alkyl styrene having one or more alkyl groups and the cross-linking reaction group of the second monomer is at least one of epoxy group, glycidyl group, hydroxyl group, acryloyl group, methacryloyl group, and allyl group, the cross-linking copolymer material having excellent characteristics is stably and easily formed, so that higher effects are obtained.

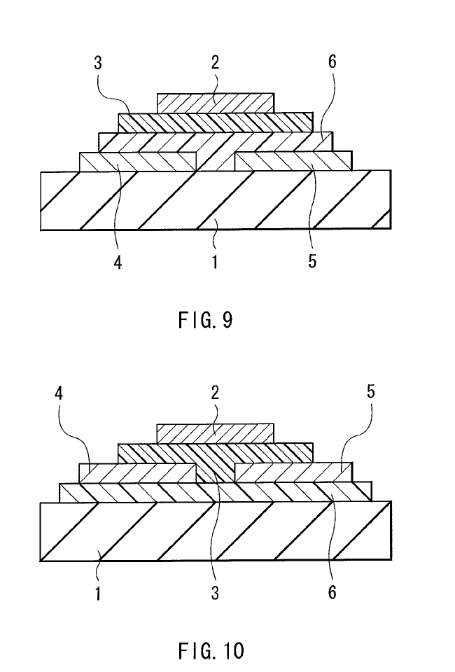

The organic TFT is not limited to the bottom-gate bottom-contact type as illustrated in FIG. 1 but may be of the bottom-gate top-contact type, top-gate bottom-contact type, or top-gate top-contact type as illustrated in FIGS. 8 to 10 corresponding to FIG. 1.

In the bottom-gate top-contact type, as illustrated in FIG. 8, the gate electrode 2, the gate insulating layer 3, the organic semiconductor layer 6, and the source electrode 4 and the drain electrode 5 are stacked in this order on the substrate 1. In the top-gate bottom-contact type, as illustrated in FIG. 9, the source electrode 4 and the drain electrode 5, the organic semiconductor layer 6, the gate insulating layer 3, and the gate electrode 2 are stacked in this order on the substrate 1. In the top-gate top-contact type, as illustrated in FIG. 10, the organic semiconductor layer 6, the source electrode 4 and the drain electrode 5, the gate insulating layer 3, and the gate electrode 2 are stacked in this order on the substrate 1.

The organic TFTs are manufactured by procedures similar to that of the organic TFT of the bottom-gate bottom-contact type except for changing the order of forming the series of components. In this case as well, the gate insulating layer 3 is adjacent to the organic semiconductor layer 6, so that the performance is improved. Obviously, also in the cases illustrated in FIGS. 8 to 10, like in the case of FIG. 7, the insulating layer 12 and the wirings 13 and 14 may be formed.

### 2. Application Example of Thin Film Transistor (Electronic Device)

Next, an application example of the above-described thin film transistor (organic TFT) will be described. The organic TFT is applicable to various electronic devices.

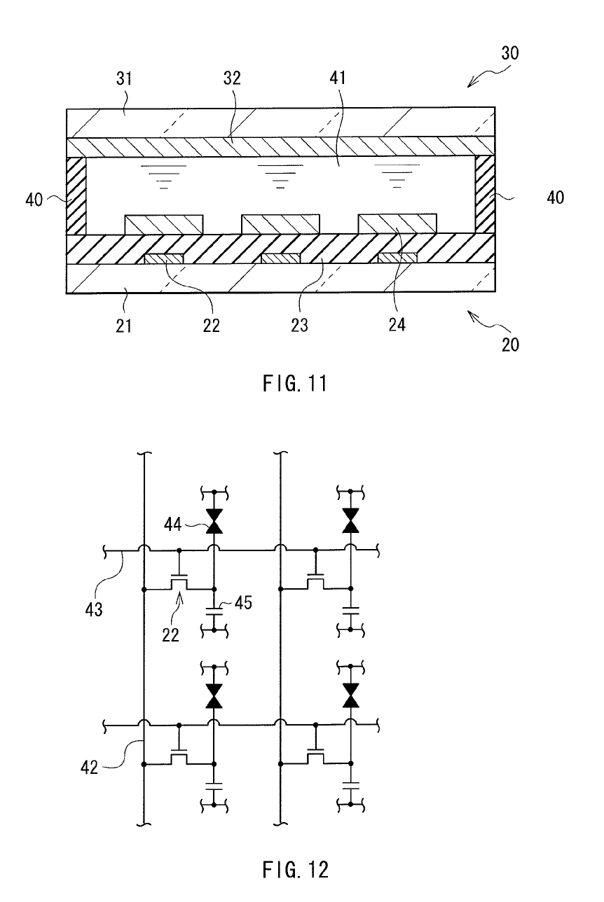

The organic TFT is applied, for example, as an electronic device to a liquid crystal display. FIGS. 11 and 12 illustrate a sectional configuration and a circuit configuration, respectively, of a main part of the liquid crystal display. A device configuration (FIG. 11) and a circuit configuration (FIG. 12) to be described below are just an example and they may be properly changed.

### Configuration of Electronic Device

The liquid crystal display to be described below is, for example, a transmissive liquid crystal display of an active matrix driving method using the organic TFT. The organic TFT is used as an element for switching (pixel selection). In the liquid crystal display, as illustrated in FIG. 11, a liquid crystal layer 41 is sealed between a drive substrate 20 and an opposed substrate 30.

In the drive substrate 20, for example, an organic TFT 22, a planarized insulating layer 23, and a pixel electrode 24 are formed in this order on one surface of a supporting substrate 21, and a plurality of organic TFTs 22 and pixel electrodes 24 are disposed in a matrix.

The supporting substrate 21 is made of, for example, a transmissive material such as glass or plastic material, and the organic TFT 22 has a configuration similar to that of the above-described thin film transistor. The kinds of the plastic material are, for example, similar to those of the case described with respect to the thin film transistor. The planarized insulating layer 23 is made of, for example, an insulating resin material such as polyimide, and the pixel electrode 24 is formed of, for example, a transmissive conductive material such as indium tin oxide (ITO). The pixel electrode 24 is connected to the organic TFT 22 via a contact hole (not illustrated) formed in the planarized insulating layer 23.

The opposed substrate 30 is obtained by forming an opposed electrode 32 on one face of a supporting substrate 31. The supporting substrate 31 is made of, for example, a transmissive material such as glass or plastic material, and the opposed electrode 32 is made of, for example, a conductive material such as ITO. The kinds of the plastic material are, for example, similar to those in the case describing the thin film transistor.

The drive substrate 20 and the opposed substrate 30 are adhered to each other by a sealing member 40 so that the pixel electrode 24 and the opposed electrode 32 are opposed to each other while sandwiching the liquid crystal layer 41. The kind of the liquid crystal molecules (liquid crystal material) included in the liquid crystal layer 41 is arbitrarily selectable.

In addition, the liquid crystal display may have other components (not illustrated) such as a retarder, a polarizer, an alignment film, and a backlight unit.

The circuit for driving the liquid crystal display includes, for example, as illustrated in FIG. 12, a capacitor 45 together with the organic TFT 22 and a liquid crystal display element 44 (the pixel electrode 24, the opposed electrode 32, and the liquid crystal layer 41). In the circuit, a plurality of signal lines 42 are arranged in the row direction and a plurality of scanning lines 43 are arranged in the column direction, and the organic TFT 22, the liquid crystal display element 44, and the capacitor 45 are disposed in a position where the signal line 42 and the scanning line 43 cross each other. The signal lines 42 and the scanning lines 43 are connected to a not-illustrated signal line drive circuit (data driver) and a not-illustrated scanning line drive circuit (scan driver), respectively. The places to which the source electrode, the gate electrode, and the drain electrode in the organic TFT 22 are connected are not limited to those illustrated in FIG. 12.

Operation of Electronic Device

In the liquid crystal display, when the pixel electrode 24 is selected by the organic TFT 22 and an electric field is applied across the pixel electrode 24 and the opposed electrode 32, the orientation state of the liquid crystal layer 41 (liquid crystal molecules) changes according to the intensity of the electric field. Consequently, the transmission amount of light (transmittance) is controlled according to the orientation state of the liquid crystal molecules, so that a tone image is displayed.

Operation and Effect on Electronic Device

In the liquid crystal display, the organic TFT 22 has a configuration similar to that of the above-described thin film transistor, so that the mobility of the organic TFT 22 and the on/off ratio improve. Therefore, the display performance is improved.

In particular, when a flexible substrate such as plastic material is used as the substrate of the organic TFT 22 (the substrate 1 of a thin film transistor), a foldable liquid crystal display is realized.

The liquid crystal display is not limited to that of the transmissive type but may be of the reflection type.

### EXAMPLES

Examples of the present disclosure will now be described in detail.

### Examples 1 to 3

An organic TFT of the bottom-gate bottom-contact type was manufactured by the following procedure.

First, an adhesion layer (titanium thin film) and a gate electrode (gold thin film) were formed in this order on a substrate (PES substrate) by using the vacuum evaporation method and the lift-off method. The procedure of the lift-off method is similar to that in the case described in the method of manufacturing the thin film transistor.

Next, in a reactor vessel, α-methylstyrene as the first monomer and glycidyl methacrylate as the second monomer were suspension-polymerized. In this case, the mixture ratio of the first and second monomers (weight ratio) was set to 50:1, 20:1, or 10:1. Subsequently, the inside of the reaction vessel was substituted with nitrogen (N₂), the temperature was increased to reaction (copolymerization) temperature of 40° C. to 120° C. both inclusive and, after that, a mixture solution of a polymerization initiator, a molecular weight adjusting agent, and an organic solvent was dropped. After that, a reaction solution was aged to complete the copolymerization reaction. Subsequently, water was removed from the reaction solution by using a vacuum drier to obtain a solid-state material. The solid-state material was pulverized to obtain a copolymer material.

The copolymer material, 3-methyl-1,2,3,6-tetrahydrophthalic acid anhydride as a curing agent, and N,N-dimethylcyclohexylamine as an amine curing catalyst were dissolved in PGMEA to prepare a solution. In this case, the mixture ratio (weight ratio) of the copolymer material, the curing material, and the catalyst was set to 100:4:3 (example 1), 100:10:3 (example 2), and 10:20:3 (example 3).

The solution was applied to the substrate and the gate electrode by spin coating and heated at 150° C. for two hours in atmosphere. Since the copolymer material was cross-linked (cured) by the operation, a gate insulating layer was formed.

Subsequently, by using the vacuum evaporation method and the lift-off method, an adhesion layer (titanium thin film), a source electrode (gold thin film), and a drain electrode were formed in this order.

An organic semiconductor material was dissolved in xylene to prepare a solution. The solution was coated by spin coating and dried to form an organic semiconductor layer. As the organic semiconductor material, a dioxane anthanthrene compound (derivative of peri-xanthenoxanthene) expressed by formula 1 was used.

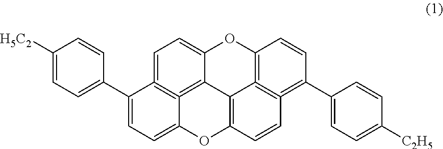

Finally, the organic semiconductor layer was etched by using the wet etching method. As a result, the organic TFT was completed.

### Examples 4 and 5

A cross-linked copolymer material (polymethacrylic acid glycidyl) was formed by using only glycidyl methacrylate as the second monomer, or a nonbridging copolymer material (poly-α-methylstyrene) was formed by using only α-methylstyrene as the first monomer. In the former case, the mixture ratio (weight ratio) of the polymer material, the curing agent, and the catalyst was set to 100:10:1. In the latter case, the curing agent and the catalyst were not used. The other procedure was similar to that of the examples 1 to 3.

The performances (mobility, on-off ratio, and hysteresis) of the organic TFT were examined in the thermally neutral environment (23° C.) and the result illustrated in Table 1 was obtained. With respect to the hysteresis, a check was made to see whether hysteresis occurs or not when voltage to be applied to the gate electrode was increased/decreased while measuring current flowing in the source electrode and the drain electrode.

TABLE 1

| | Organic semiconductor layer | | | | | |
|---|---|---|---|---|---|---|
| | | | Weight | | | |
| Table 1 | First monomer | Second monomer | ratio | Mobility | On/off ratio | Hysteresis |
| Example 1 | α-methylstyrene | glycidyl methacrylate | 50:1 | 0.9 | 10⁷ | None |
| Example 2 | α-methylstyrene | glycidyl methacrylate | 20:1 | 0.6 | 10⁷ | None |
| Example 3 | α-methylstyrene | glycidyl methacrylate | 10:1 | 0.5 | 10⁶ | None |
| Example 4 | — | glycidyl methacrylate | — | 0.01 | 10² | Occurred |
| Example 5 | α-methylstyrene | — | — | unmeasurable | unmeasurable | unmeasurable |

In the case of forming the cross-linked copolymer material by using the first and second monomers (examples 1 to 3), the mobility and the on-off ratio are considerably higher than those in the case of forming no cross-linked copolymer material (examples 4 and 5) and no hysteresis occurred. In the case of using only the first monomer (example 5), the gate insulating layer was dissolved by the organic solvent in the process of manufacturing the organic TFT, so that the mobility and the like were unmeasurable.

Although the present disclosure has been described above by the embodiments, the disclosure is not limited to the modes described in the embodiments but may be variously modified. For example, an electronic device to which the thin film transistor of an embodiment of the present disclosure is applied is not limited to the liquid crystal display but may be other display devices. Examples of the other display devices include an organic electroluminescence (EL) display device and an electronic paper display device. In those cases as well, the display performance can be improved. The thin film transistor of an embodiment of the disclosure may be applied to an electronic device other than a display device.

The present disclosure contains subject matter related to that disclosed in Japanese Priority Patent Application JP 2010-127896 filed in the Japan Patent Office on Jun. 3, 2010, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A thin film transistor comprising:
a gate electrode;
an organic semiconductor layer; and
a gate insulating layer which is positioned between the gate electrode and the organic semiconductor layer and is adjacent to the organic semiconductor layer,
wherein the gate insulating layer contains a material in which a first monomer as at least one of styrene and a derivative of styrene, and a second monomer having carbon-carbon double bond and a cross-linking reaction group are copolymerized and cross-linked.

2. The thin film transistor according to claim 1, wherein the cross-linking reaction group is at least one of an epoxy group (—C₂H₃O), a glycidyl group (—CH₂—C₂H₃O), a hydroxyl group (—OH), an acryloyl group (—CO—CH═CH₂), a methacryloyl group (—CO—C(CH₃)═CH₂), and an alyl group (—CH₂—CH═CH₂).

3. The thin film transistor according to claim 1, wherein the derivative of styrene is alkyl styrene having one or more alkyl groups.

4. The thin film transistor according to claim 1, wherein the first monomer is at least one of α-methylstyrene, α-ethylstyrene, α-butylstyrene, and 4-methyl-styrene and their derivatives.

5. The thin film transistor according to claim 1, wherein the second monomer is at least one of glycidyl acrylate, glycidyl methacrylate, and allylglycidylether and their derivatives.

6. A method of manufacturing a thin film transistor, comprising:
forming a gate electrode;
forming an organic semiconductor layer; and
forming a gate insulating layer between the gate electrode and the organic semiconductor layer so as to be adjacent to the organic semiconductor layer, the gate insulating layer containing a material in which a first monomer as at least one of styrene and a derivative of styrene, and a second monomer having carbon-carbon double bond and a cross-linking reaction group are copolymerized and cross-linked.

7. An electronic device having a thin film transistor comprising a gate electrode, an organic semiconductor layer, and a gate insulating layer which is positioned between the gate electrode and the organic semiconductor layer and is adjacent to the organic semiconductor layer,
wherein the gate insulating layer contains a material in which a first monomer as at least one of styrene and a derivative of styrene, and a second monomer having carbon-carbon double bond and a cross-linking reaction group are copolymerized and cross-linked.
